(19) United States
(12) Patent Application Publication
(10) Pub. No.: US 2026/0337818 A1
(43) Pub. Date: Oct. 29, 2026

(54) METHOD FOR GROWING BLACK PHOSPHORUS ON CARBON SUBSTRATE USING CHEMICAL VAPOR TRANSPORT AND ENERGY STORAGE DEVICE USING THE SAME

(71) Applicant: RESEARCH & BUSINESS FOUNDATION SUNGKYUNKWAN UNIVERSITY, Suwon-si (KR)

(72) Inventors: HOSEOK PARK, Yongin-si (KR); Taehun Kang, Suwon-si (KR); Jinsuk Byun, Suwon-si (KR)

(21) Appl. No.: 19/646,879

(22) Filed: Apr. 14, 2026

(30) Foreign Application Priority Data
Apr. 24, 2025 (KR) 10-2025-0053703

(51) Int. Cl. C30B 29/02; C30B 25/18; H01M 4/38; H01M 4/583

(52) U.S. Cl. CPC C30B 29/02; C30B 25/18; H01M 4/38; H01M 4/583

(57) ABSTRACT

The present disclosure relates to a method for directly synthesizing black phosphorus on a carbon substrate, the method comprising: coating a mineralizer on a surface of the carbon substrate; and growing black phosphorus on the surface of the carbon substrate by placing the carbon substrate coated with the mineralizer and a black phosphorus precursor in a reactor and subsequently reacting them.

### FIELD

The present invention relates to a method for directly growing black phosphorus, which is a two-dimensional elemental material, on a carbon substrate, and to a technology for utilizing the resulting black phosphorus-carbon composite as an anode material for an alkali metal ion battery.

### DESCRIPTION OF THE RELATED ART

As consumption of fossil fuels increases, climate change, air pollution, and environmental problems have emerged as serious issues, and development of efficient energy storage devices together with eco-friendly energy sources has become essential to solve these problems. In particular, alkali metal ion batteries such as lithium ion batteries play a key role in various fields of modern society, including electronic devices and electric vehicles.

Conventional lithium ion batteries have been associated with problems caused by limited lithium reserves and unstable price fluctuations. To overcome these issues, sodium ion batteries have been studied as an alternative. However, hard carbon anodes, which are mainly used in sodium ion batteries, have limitations in realizing high-capacity, high-energy-density batteries due to their low theoretical capacity (350 mAh/g). To address these limitations, high-capacity materials such as silicon have been studied as alternatives, but they frequently suffer from detachment from the substrate due to significant volume expansion during charging and discharging, resulting in a rapid decrease in capacity and shortened lifespan. Accordingly, there has been a continuous need for development of alternative materials that exhibit higher energy density and capacity than conventional hard carbon while having better stability than silicon.

Recently, black phosphorus, which is a two-dimensional material, has attracted attention as an anode material for next-generation energy storage devices because it has excellent ion mobility and a high theoretical capacity (2,596 mAh/g for Na) due to its high specific surface area and unique zigzag structure. However, in conventional methods, bulk black phosphorus is first prepared and then exfoliated and modified again through a complicated electrode fabrication process involving addition of a conductive agent and a binder. Since such methods require a two-step black phosphorus synthesis process and a separate electrode fabrication step, they have disadvantages in that the process is complicated and the cost is increased.

Meanwhile, methods for directly growing and coating graphene through chemical vapor deposition (CVD) have been developed, and research aimed at minimizing process steps has been actively conducted. Similarly, there is a need to simplify the process of using black phosphorus in electrodes, and in particular, there is a demand for an innovative method for efficiently preparing black phosphorus as an electrode material for energy storage devices.

Korean Patent Registration No. 10-0788487, which is background art of the present disclosure, relates to a method for preparing black phosphorus and a black phosphorus-carbon composite, the prepared black phosphorus and black phosphorus-carbon composite, and a lithium secondary battery including the same and a method of using the same.

### DESCRIPTION

### Technical Problem

The present disclosure has been made to solve the problems of the above-described conventional art, and provides a method for directly growing black phosphorus on a carbon substrate through a chemical vapor transport method.

The present disclosure also provides a carbon substrate-black phosphorus composite prepared by the above method.

The present disclosure also provides an anode material for an alkali metal ion battery, comprising the carbon substrate-black phosphorus composite.

The present disclosure also provides an energy storage device, a supercapacitor, and an energy storage element for a wearable electronic device using the carbon substrate-black phosphorus composite.

However, the technical problems to be achieved by the embodiments of the present disclosure are not limited to the technical problems described above, and there may be other technical problems.

### Means for Solving the Problem

As a technical means for achieving the above-described technical problems, a first aspect of the present disclosure provides a method for directly synthesizing black phosphorus on a carbon substrate, the method comprising: coating a mineralizer on a surface of the carbon substrate; and growing black phosphorus on the surface of the carbon substrate by placing the carbon substrate coated with the mineralizer and a black phosphorus precursor in a reactor and subsequently reacting them.

According to one embodiment of the present disclosure, the black phosphorus may be grown on the surface of the carbon substrate with a controlled orientation, but is not limited thereto.

According to one embodiment of the present disclosure, the mineralizer may be selected from the group consisting of Sn, SnI₂, SnI₄, SnCl₂, SnCl₄, Pb, PbI₂, PbCl₂, Au, AuCl₃ and combinations thereof, but is not limited thereto.

According to one embodiment of the present disclosure, the carbon substrate may be selected from the group consisting of graphite film, carbon cloth, carbon nanotubes, graphene film, activated carbon, porous carbon, carbon fibers, buckypaper and combinations thereof, but is not limited thereto.

According to one embodiment of the present disclosure, the black phosphorus precursor may comprise red phosphorus, white phosphorus, and phosphorus allotropes, but is not limited thereto.

According to one embodiment of the present disclosure, the black phosphorus precursor may further comprise a mineralizer of the same type as the mineralizer used for coating the carbon substrate, but is not limited thereto.

According to one embodiment of the present disclosure, the coating and the growing may be performed using a chemical vapor transport method, but are not limited thereto.

According to one embodiment of the present disclosure, the coating of the mineralizer may be performed at a temperature in a range of 550 °C to 900 °C, but is not limited thereto.

According to one embodiment of the present disclosure, the growing black phosphorus may be performed at a temperature in a range of 400 °C to 600 °C for 1 minute to 12 hours, but is not limited thereto.

According to one embodiment of the present disclosure, the method may further comprise cooling to room temperature for stabilization of the black phosphorus, wherein the cooling to room temperature may be performed for 4 hours to 24 hours, but is not limited thereto.

In addition, a second aspect of the present disclosure provides a carbon substrate-black phosphorus composite, comprising: a carbon substrate; and black phosphorus grown on a surface of the carbon substrate with a controlled orientation.

According to one embodiment of the present disclosure, the black phosphorus may have a form in which a plurality of films are stacked, but is not limited thereto.

According to one embodiment of the present disclosure, the black phosphorus may be bonded onto the carbon substrate by forming a chemical bond at an interface with the carbon substrate, but is not limited thereto.

According to one embodiment of the present disclosure, the carbon substrate-black phosphorus composite may be free of a conductive agent and a binder, but is not limited thereto.

According to one embodiment of the present disclosure, the black phosphorus may be crystalline, but is not limited thereto.

In addition, a third aspect of the present disclosure provides an anode material for an alkali metal ion battery, comprising the carbon substrate-black phosphorus composite according to the second aspect of the present disclosure.

According to one embodiment of the present disclosure, the alkali metal may be lithium or sodium, but is not limited thereto.

According to one embodiment of the present disclosure, migration of the alkali metal ions may be enhanced by the black phosphorus, but is not limited thereto.

In addition, a fourth aspect of the present disclosure provides an energy storage device, comprising the carbon substrate-black phosphorus composite according to the second aspect of the present disclosure.

In addition, a fifth aspect of the present disclosure provides a supercapacitor, comprising the carbon substrate-black phosphorus composite according to the second aspect of the present disclosure.

In addition, a sixth aspect of the present disclosure provides an energy storage element for a wearable electronic device, comprising the carbon substrate-black phosphorus composite according to the second aspect of the present disclosure.

The above-described means for solving the technical problems are merely exemplary and should not be construed as limiting the present disclosure. In addition to the above-described exemplary embodiments, additional embodiments may be provided in the drawings and the detailed description of the invention.

### Effect of the Invention

The method for directly synthesizing black phosphorus on a carbon substrate according to the present disclosure can greatly reduce process cost and time by simplifying the conventional two-step process (black phosphorus synthesis and electrode fabrication) into a one-step process. Specifically, by directly growing black phosphorus on the carbon substrate through a chemical vapor transport method using a red phosphorus precursor and a mineralizer, the resulting material can be used directly as an electrode material for an energy storage device without a separate exfoliation or electrode fabrication process.

In addition, the carbon substrate-black phosphorus composite according to the present disclosure provides excellent electrochemical properties even without using a conductive agent and a binder. The absence of the conductive agent and the binder can increase the energy density of the electrode material, and the chemical vapor transport method can form a chemical bond between the carbon substrate and the black phosphorus, thereby reducing electrical contact resistance and promoting electron transport.

Furthermore, the carbon substrate-black phosphorus composite prepared by the method according to the present disclosure has a black phosphorus structure with a controlled orientation, thereby optimizing migration pathways of alkali metal ions. Such structural characteristics can reduce ion resistance and improve capacity compared to conventional black phosphorus, and can also effectively relieve stress caused by volume expansion, thereby significantly improving long-term stability.

In addition, the anode material for an alkali metal ion battery using the carbon substrate-black phosphorus composite according to the present disclosure can provide higher energy density and capacity than a conventional graphite anode, while exhibiting better cycle stability than a silicon anode. In particular, the chemical bond between the black phosphorus and the carbon substrate can suppress electrode detachment caused by volume expansion, thereby maintaining stable performance during charge-discharge cycles.

In addition, the carbon substrate-black phosphorus composite according to the present disclosure is applicable not only to alkali metal ion batteries, but also to various energy storage devices such as supercapacitors and energy storage elements for wearable electronic devices, and may make a significant contribution to the development of next-generation energy storage systems requiring high energy density and stability. Accordingly, the present disclosure can promote research related to improvement of energy efficiency and development of sustainable energy solutions in various fields, including electric vehicles, portable electronic devices, and renewable energy storage systems.

However, the effects that can be obtained from the present disclosure are not limited to the effects described above, and there may be other effects.

### BRIEF DESCRIPTION OF THE DRAWING

The patent or application file contains at least one drawing executed in color. Copies of this patent or patent application publication with color drawing(s) will be provided by the Patent and Trademark Office upon request and payment of the necessary fee.

FIG. 1 is a flowchart of a method for directly synthesizing black phosphorus on a carbon substrate according to one embodiment of the present disclosure.

FIG. 2 shows an SEM image and an EDS image of an Sn-coated graphite film according to one example of the present disclosure.

FIG. 3 is a schematic diagram of a method for directly synthesizing black phosphorus on a carbon substrate according to one example of the present disclosure.

FIG. 4 shows top-view and cross-sectional SEM images of a graphite film on which black phosphorus has been grown according to one example of the present disclosure.

FIG. 5 is a cross-sectional EDS mapping image of a graphite film on which black phosphorus has been grown according to one example of the present disclosure.

FIG. 6 is a particle image of grown black phosphorus according to one example of the present disclosure.

FIG. 7 is an HR-TEM image of black phosphorus according to one example of the present disclosure.

FIG. 8 is an XRD spectrum of a graphite film on which black phosphorus has been grown according to one example of the present disclosure.

FIG. 9 shows results of measuring initial 2-cycle volumetric capacity and rate performance of an alkali battery using a graphite film on which black phosphorus has been grown according to Example 2 of the present disclosure.

### DETAILED DESCRIPTION

Hereinafter, embodiments of the present disclosure will be described in detail so as to be easily implemented by those skilled in the art, with reference to the accompanying drawings. However, the present disclosure may be embodied in many different forms and are not limited to the examples to be described herein. In addition, parts not related with the description have been omitted in order to clearly describe the present disclosure in the drawings and throughout the present specification, like reference numerals designate like elements.

Further, throughout this specification, when a certain part is “connected” with the other part, it is meant that the certain part may be “directly connected” with the other part and “electrically connected” with the other part with another element interposed therebetween.

Throughout the present specification, it will be understood that when a certain member is located “on”, “above”, “at the top of”, “under”, “below”, and “at the bottom of” the other member, a certain member is in contact with the other member and another member may also be present between the two members.

Throughout the specification, a case where a part “includes” an element will be understood to imply the inclusion of stated elements but not the exclusion of any other elements unless explicitly described to the contrary.

The terms “about”, “substantially”, and the like to be used in the specification are used as a numerical value or a value close to the numerical value when inherent manufacturing and material tolerances are presented in the stated meaning, and used to prevent an unscrupulous infringer from unfairly using disclosed contents in which precise or absolute numerical values are mentioned to help in the understanding of the present disclosure. Throughout the present specification, the term of “step to” or “step of” does not mean “step for”.

Throughout the present specification, the term “combinations thereof” included in the expression of the Markush form means one or more mixtures or combinations selected from the group consisting of components described in the expression of the Markush form, and means to include at least one selected from the group consisting of the components.

Throughout the present specification, “A and/or B” means “A or B, or A and B”.

Hereinafter, a method for directly synthesizing black phosphorus on a carbon substrate according to the present disclosure and an energy storage device using the same will be described in detail with reference to embodiments, examples, and the accompanying drawings. However, the present disclosure is not limited to such embodiments, examples, and drawings.

As a technical means for achieving the above-described technical problems, a first aspect of the present disclosure provides a method for directly synthesizing black phosphorus on a carbon substrate, the method comprising: coating a mineralizer on a surface of the carbon substrate; and growing black phosphorus on the surface of the carbon substrate by placing the carbon substrate coated with the mineralizer and a black phosphorus precursor in a reactor and subsequently reacting them.

The present invention relates to a method for directly growing black phosphorus, which is a two-dimensional elemental material, on a carbon substrate, and provides an innovative method for simplifying a conventional two-step process involving preparation of bulk black phosphorus followed by exfoliation and electrode fabrication into a one-step process. Through this, process cost can be reduced and energy storage performance can be improved.

According to one embodiment of the present disclosure, the coating and the growing may be performed using a chemical vapor transport method, but are not limited thereto.

In the present invention, both the mineralizer coating step and the black phosphorus growth step may be performed through a chemical vapor transport method. The chemical vapor transport method is a method in which a material is vaporized at a high temperature, transported in a gaseous state, and then deposited at a desired location, thereby enabling uniform, high-quality coating and crystal growth. The reaction proceeds in a vacuum-sealed glass tube, and coating and black phosphorus growth having desired characteristics may be achieved by controlling conditions such as temperature, pressure, and time. However, the present invention is not limited only to the chemical vapor transport method, and may also be performed by other suitable methods.

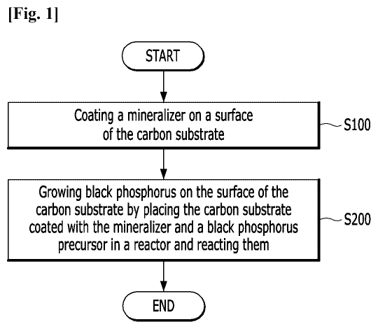

Referring to FIG. 1, as a first step for directly synthesizing black phosphorus on a carbon substrate, a mineralizer is coated on a surface of the carbon substrate (S100).

This step is an essential pretreatment process for growth of black phosphorus, and serves to activate the surface of the carbon substrate to increase reactivity with phosphorus (P) atoms. A typical carbon substrate has insufficient reactivity with phosphorus, and thus, without a mineralizer, black phosphorus does not grow on the substrate surface but instead independently grows in bulk form on the wall surface of the glass tube. By providing nucleation sites on the substrate surface through mineralizer coating, an environment is created in which black phosphorus can directly grow on the surface of the carbon substrate.

According to one embodiment of the present disclosure, the mineralizer may be selected from the group consisting of Sn, SnI₂, SnI₄, SnCl₂, SnCl₄, Pb, PbI₂, PbCl₂, Au, AuCl₃ and combinations thereof, but is not limited thereto.

The mineralizer used in the present invention is coated on the surface of the carbon substrate and serves to increase reactivity with phosphorus atoms, and may include a metal simple substance or a metal halide. For example, Sn-based compounds such as Sn, SnI₂, SnI₄, SnCl₂, and SnCl₄; Pb-based compounds such as Pb, PbI₂, and PbCl₂; and Au-based compounds such as Au and AuCl₃ may be used, either alone or in combination. Such mineralizers promote transport and crystallization of phosphorus atoms, and contribute to formation of a bond between the substrate and the black phosphorus. The type and concentration of the mineralizer may affect the structure and properties of the grown black phosphorus. Preferably, the mineralizer may include an Sn-based compound, and in particular, Sn and SnI4 may function as mineralizers that form a uniform coating layer on the surface of the carbon substrate and effectively provide nucleation sites for growth of black phosphorus.

According to one embodiment of the present disclosure, the carbon substrate may be selected from the group consisting of graphite film, carbon cloth, carbon nanotubes, graphene film, activated carbon, porous carbon, carbon fibers, buckypaper and combinations thereof, but is not limited thereto.

In the present invention, various forms of carbon substrates may be used. Graphite film may be an ideal substrate for growth of black phosphorus due to its layered structure and high electrical conductivity, but various other forms of carbon materials may also be used, including carbon cloth, carbon nanotubes, graphene film, activated carbon, porous carbon, carbon fibers, and buckypaper. These various carbon substrates each have unique structural and electrical properties, which may affect performance of the final product. In particular, a carbon substrate having a porous structure provides a large surface area and thus more space in which black phosphorus can grow, which may contribute to improvement in energy storage capacity.

According to one embodiment of the present disclosure, the coating of the mineralizer may be performed at a temperature in a range of 550 °C to 900 °C, but is not limited thereto.

This temperature range provides suitable conditions under which the mineralizer can be converted into a gaseous phase and uniformly coated on the surface of the carbon substrate. At temperatures below 550 °C, vaporization of the mineralizer does not occur sufficiently, resulting in low coating efficiency, whereas at temperatures above 900 °C, damage to the carbon substrate or undesired side reactions may occur. Therefore, selection of an appropriate temperature range is important for uniform and effective mineralizer coating. The coating process is generally carried out for about 4 hours to 12 hours, during which the mineralizer is sufficiently coated on the surface of the carbon substrate to complete preparation for subsequent growth of black phosphorus.

Subsequently, as a second step for directly synthesizing black phosphorus on the carbon substrate, the carbon substrate coated with the mineralizer and a black phosphorus precursor are placed in a reactor and then reacted so that black phosphorus is grown on the surface of the carbon substrate (S200).

When the carbon substrate coated with the mineralizer is prepared, it is placed in the reactor together with the black phosphorus precursor and reacted, so that black phosphorus is directly grown on the surface of the carbon substrate. In this process, the black phosphorus precursor is vaporized and exists in a gaseous state, and nucleation and crystal growth occur on the surface of the carbon substrate coated with the mineralizer. The reactor generally uses a glass tube, and the interior thereof is maintained under vacuum. This step should be carried out under appropriate temperature and time conditions, through which black phosphorus having desired properties can be directly grown on the carbon substrate.

According to one embodiment of the present disclosure, the black phosphorus precursor may comprise red phosphorus, white phosphorus, and phosphorus allotropes, but is not limited thereto.

As the precursor for synthesizing black phosphorus in the present invention, red phosphorus, white phosphorus, and phosphorus allotropes other than these may be used. Through the chemical vapor transport method, the black phosphorus precursor is vaporized at a high temperature and exists in a gaseous state, and the phosphorus atoms in the gaseous state reach the surface of the carbon substrate coated with the mineralizer and crystallize into black phosphorus. Preferably, red phosphorus may be used, since red phosphorus is relatively stable and easy to handle among phosphorus allotropes, is suitable for synthesizing black phosphorus, and is relatively readily available, making it advantageous for industrial application.

According to one embodiment of the present disclosure, the black phosphorus precursor may further comprise a mineralizer of the same type as the mineralizer used for coating the carbon substrate, but is not limited thereto.

In addition to red phosphorus, the black phosphorus precursor may further comprise a mineralizer of the same type as that used for coating the carbon substrate. For example, when Sn and SnI4 are used for coating the carbon substrate, the same Sn and SnI4 may also be additionally used in the black phosphorus precursor. Such an additional mineralizer serves to promote transport of phosphorus and assist crystal growth of black phosphorus during the chemical vapor transport process. In addition, the mineralizer acts as a transport agent during the reaction to help phosphorus atoms move uniformly to the surface of the carbon substrate, thereby contributing to formation of a uniform black phosphorus layer.

According to one embodiment of the present disclosure, the growing black phosphorus may be performed at a temperature in a range of 400 °C to 600 °C for 1 minute to 12 hours, but is not limited thereto.

This temperature range provides suitable conditions under which red phosphorus is vaporized and exists in a gaseous state and reacts on the surface of the carbon substrate coated with the mineralizer to crystallize into black phosphorus. At temperatures below 400 °C, vaporization of red phosphorus may not occur sufficiently or crystallization may be incomplete, whereas at temperatures above 600 °C, stability of black phosphorus may decrease or other phosphorus allotropes may be formed. In addition, when the reaction time is less than 1 minute, sufficient nucleation and crystal growth of black phosphorus may not occur, whereas when the reaction time exceeds 12 hours, non-uniformity in the black phosphorus structure due to overgrowth may occur.

According to one embodiment of the present disclosure, the method may further comprise cooling to room temperature for stabilization of the black phosphorus, wherein the cooling to room temperature may be performed for 4 hours to 24 hours, but is not limited thereto.

Meanwhile, after the black phosphorus growth reaction, a step of cooling to room temperature may be performed. The cooling to room temperature may be performed for 4 hours to 24 hours, and such a cooling process is important for improving crystallinity of black phosphorus and enhancing structural stability. When the cooling time is less than 4 hours, defects may occur in the crystal structure of the black phosphorus due to a rapid temperature change, whereas when the cooling time exceeds 24 hours, process efficiency may decrease.

According to one embodiment of the present disclosure, the black phosphorus may be grown on the surface of the carbon substrate with a controlled orientation, but is not limited thereto.

The black phosphorus synthesized according to the present invention is characterized in that it is grown on the surface of the carbon substrate with a controlled orientation. The growth orientation of the black phosphorus is not particularly limited, and may include, for example, various orientations such as a vertical direction, a horizontal direction, or an intermediate angular direction with respect to the surface of the carbon substrate. Such an orientation-controlled growth structure is formed as phosphorus present in a gaseous state reacts with the substrate through the chemical vapor transport method on the carbon substrate coated with the mineralizer. The black phosphorus structure with a controlled orientation can optimize migration pathways of alkali metal ions, thereby reducing ion resistance and improving energy storage capacity as compared with a conventional black phosphorus structure. In addition, the orientation-controlled growth structure can effectively relieve stress caused by volume expansion during charging and discharging, thereby improving structural stability.

In addition, a second aspect of the present disclosure provides a carbon substrate-black phosphorus composite, comprising: a carbon substrate; and black phosphorus grown on a surface of the carbon substrate with a controlled orientation.

With respect to the carbon substrate-black phosphorus composite according to the second aspect of the present disclosure, detailed descriptions of portions overlapping with the first aspect of the present disclosure are omitted. However, even when such descriptions are omitted, the contents described in the first aspect of the present disclosure may be equally applied to the second aspect of the present disclosure.

The carbon substrate-black phosphorus composite includes a black phosphorus structure directly grown on the carbon substrate, and unlike conventional methods, may be used as an electrode material for an energy storage device even without a conductive agent and a binder. The carbon substrate provides an electron conduction pathway, and the black phosphorus grown thereon provides high energy storage capacity through an alloying reaction with alkali metal ions. In addition, the direct growth method through the chemical vapor transport method improves bonding strength between the black phosphorus and the carbon substrate, thereby reducing electrode detachment caused by volume expansion during charging and discharging.

According to one embodiment of the present disclosure, the black phosphorus may have a form in which a plurality of films are stacked, but is not limited thereto.

In the carbon substrate-black phosphorus composite prepared according to the present invention, the black phosphorus may have a form in which a plurality of films are stacked. This is because the black phosphorus grows in a layered structure on the carbon substrate through the chemical vapor transport method. Upon cross-sectional observation, such a structure appears as a bundle of innumerable films, showing that the black phosphorus has grown in a vertical direction. Such a layered structure provides space for insertion and deintercalation of alkali metal ions and can promote ion migration, thereby contributing to improvement in electrochemical performance. In addition, the layered structure can more effectively accommodate volume changes occurring during charging and discharging, thereby enhancing structural stability.

According to one embodiment of the present disclosure, the black phosphorus may be bonded onto the carbon substrate by forming a chemical bond at an interface with the carbon substrate, but is not limited thereto.

In the carbon substrate-black phosphorus composite prepared according to the present invention, the black phosphorus may be bonded onto the carbon substrate by forming a chemical bond at an interface with the carbon substrate. While the reaction proceeds at a high temperature through the chemical vapor transport method, phosphorus atoms present in a gaseous state are bonded by forming a chemical bond at the interface with activated sites on the surface of the carbon substrate coated with the mineralizer. Such interfacial chemical bonding provides stronger bonding strength than simple physical adhesion, thereby reducing detachment of the black phosphorus from the carbon substrate even during charging and discharging in which volume expansion occurs. This can solve the problem of active material detachment observed in electrodes prepared by conventional methods, and can greatly contribute to maintaining performance of an energy storage device requiring long-term stability.

According to one embodiment of the present disclosure, the carbon substrate-black phosphorus composite may be free of a conductive agent and a binder, but is not limited thereto.

The carbon substrate-black phosphorus composite according to the present invention is characterized in that it is free of a conductive agent and a binder. In conventional electrode fabrication methods, a conductive agent for improving electrical conductivity and a binder for bonding materials are used together with black phosphorus as an active material. However, in the present invention, because black phosphorus is directly grown on a highly conductive carbon substrate through the chemical vapor transport method, a separate conductive agent is not required. In addition, since the black phosphorus is chemically bonded to the carbon substrate, a binder is also not required. An electrode free of a conductive agent and a binder can provide higher energy density because the proportion of the active material is increased, and can promote ion migration by maximizing the contact area between the electrolyte and the active material.

According to one embodiment of the present disclosure, the black phosphorus may be crystalline, but is not limited thereto.

The black phosphorus synthesized according to the present invention may have crystallinity. When the synthesis process through the chemical vapor transport method includes a slow cooling process under appropriate temperature and pressure conditions, phosphorus atoms that have existed in a gaseous state are crystallized in a regular arrangement. Crystalline black phosphorus has better electrical conductivity and structural stability than amorphous black phosphorus, and thus electrochemical performance may be improved. Crystalline black phosphorus has a regular interlayer structure, so insertion and deintercalation of alkali metal ions are facilitated, which may contribute to improvement in high-rate charge-discharge characteristics. In addition, crystalline black phosphorus is advantageous for reversible reaction with alkali metal ions, and thus may extend cycle life.

In addition, a third aspect of the present disclosure provides an anode material for an alkali metal ion battery, comprising the carbon substrate-black phosphorus composite according to the second aspect of the present disclosure.

With respect to the anode material for an alkali metal ion battery according to the third aspect of the present disclosure, detailed descriptions of portions overlapping with the second aspect of the present disclosure are omitted. However, even when such descriptions are omitted, the contents described in the second aspect of the present disclosure may be equally applied to the third aspect of the present disclosure.

Black phosphorus has a high theoretical capacity through an alloying reaction with alkali metal ions, and in particular, the composite prepared according to the present invention has a structure in which the growth orientation of black phosphorus is controlled, thereby optimizing migration pathways of alkali metal ions. In addition, mechanical stability of the electrode may be improved through chemical bonding with the carbon substrate. Due to these characteristics, the composite may contribute to development of high-capacity, high-power, and long-life batteries, and thus the carbon substrate-black phosphorus composite according to the present disclosure is suitable for use as an anode material for an alkali metal ion battery.

According to one embodiment of the present disclosure, the alkali metal may be lithium or sodium, but is not limited thereto.

Lithium ion batteries are currently the most widely used secondary batteries and provide high energy density and operating voltage. Meanwhile, sodium ion batteries have attracted attention as an alternative that improves economic efficiency by utilizing sodium, which is more abundant and less expensive than lithium. Black phosphorus can effectively undergo an alloying reaction with both lithium ions and sodium ions, and thus may be used in both types of batteries. In particular, black phosphorus can provide a high theoretical capacity through an alloying reaction with lithium, and the carbon substrate-black phosphorus composite prepared according to the present invention may be used as a suitable anode material for such alkali metal ion batteries.

According to one embodiment of the present disclosure, migration of the alkali metal ions may be enhanced by the black phosphorus, but is not limited thereto.

In the anode material according to the present invention, migration of alkali metal ions may be enhanced due to the black phosphorus structure having a controlled orientation. In a typical black phosphorus structure, ion migration may be restricted because the interlayer spacing is narrow or ion migration pathways are complicated. However, in the composite prepared according to the present invention, the growth orientation of black phosphorus is controlled so that the interlayer structure is regularly arranged, thereby providing pathways through which alkali metal ions can be easily inserted and deintercalated. This can reduce ion resistance and improve the charge-discharge rate. In addition, the vertically grown structure also contributes to enhancing structural stability by effectively relieving stress caused by volume expansion during charging and discharging.

In addition, a fourth aspect of the present disclosure provides an energy storage device, comprising the carbon substrate-black phosphorus composite according to the second aspect of the present disclosure.

With respect to the energy storage device according to the fourth aspect of the present disclosure, detailed descriptions of portions overlapping with the second aspect of the present disclosure are omitted. However, even when such descriptions are omitted, the contents described in the second aspect of the present disclosure may be equally applied to the fourth aspect of the present disclosure.

An energy storage device is a device that stores electrical energy in a chemical form and converts it back into electrical energy when needed, and the carbon substrate-black phosphorus composite prepared according to the present invention may be used as an electrode material for various energy storage devices due to its high energy storage capacity and stable structural characteristics. In particular, improved mechanical stability through chemical bonding and promoted ion migration through the vertically grown structure may contribute to development of high-performance energy storage devices.

In addition, a fifth aspect of the present disclosure provides a supercapacitor, comprising the carbon substrate-black phosphorus composite according to the second aspect of the present disclosure.

With respect to the supercapacitor according to the fifth aspect of the present disclosure, detailed descriptions of portions overlapping with the second aspect of the present disclosure are omitted. However, even when such descriptions are omitted, the contents described in the second aspect of the present disclosure may be equally applied to the fifth aspect of the present disclosure.

A supercapacitor is a device that stores energy through formation of an electric double layer or surface pseudocapacitance, and is characterized by a rapid charge-discharge rate and a long lifespan. The carbon substrate-black phosphorus composite prepared according to the present invention can greatly improve performance of a supercapacitor by combining a carbon substrate having a high specific surface area and excellent electrical conductivity with black phosphorus having improved ion accessibility due to the vertically grown structure. In particular, the structure free of a conductive agent and a binder can maximize contact area with an electrolyte, thereby providing high-output characteristics.

In addition, a sixth aspect of the present disclosure provides an energy storage element for a wearable electronic device, comprising the carbon substrate-black phosphorus composite according to the second aspect of the present disclosure.

With respect to the energy storage element for a wearable electronic device according to the sixth aspect of the present disclosure, detailed descriptions of portions overlapping with the second aspect of the present disclosure are omitted. However, even when such descriptions are omitted, the contents described in the second aspect of the present disclosure may be equally applied to the sixth aspect of the present disclosure.

A wearable electronic device is an electronic device configured to be worn on or attached to a body, and portability and flexibility are important therefor. An energy storage element used in such a device is required to have characteristics such as miniaturization, light weight, and flexibility. The carbon substrate-black phosphorus composite prepared according to the present invention is suitable for an energy storage element for a wearable electronic device due to its high energy density and excellent mechanical properties. In particular, when a flexible carbon substrate such as a graphite film is used, an energy storage element having excellent flexibility and durability can be produced, and thus may be applied to various wearable devices.

Hereinafter, the present invention will be explained in more detail through Examples, but the following Examples are for the purpose of illustration only and are not intended to limit the scope of the present disclosure.

### Example 1 Direct Synthesis of Black Phosphorus on a Carbon Substrate

### Preparation of Sn-Graphite Film (Sn-GF) Through a Chemical Vapor Transport Method

In order to prepare a graphite film coated with mineralizers (Sn and SnI₄), a chemical vapor transport method was used, and Sn metal powder and SnI4 powder were used as precursors. A graphite film was placed in a glass tube, and Sn and SnI4 powders were added thereto, followed by vacuum sealing. The vacuum-sealed glass tube was heated to 550 °C at a rate of 5 °C/min and maintained for 4 hours to allow the reaction to proceed. After completion of the reaction, the film was obtained by breaking the glass tube.

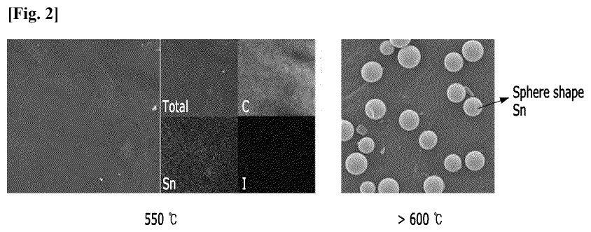

As shown in FIG. 2, after performing the chemical vapor transport method with the graphite film and Sn and SnI₄ added thereto, the surface of the graphite film was observed by SEM. On the surface of the sample reacted at 550 °C, no other particles or impurities were observed, and EDS analysis confirmed that Sn and I were uniformly distributed in a thin layer on the surface. In contrast, on the surface of the sample reacted at 600 °C or higher, it was confirmed that spherical Sn was irregularly arranged due to the high Sn vapor, thereby confirming that 550 °C was the optimal temperature.

### Method for Preparing a Graphite Film on Which Black Phosphorus is Grown Through a Chemical Vapor Transport Method

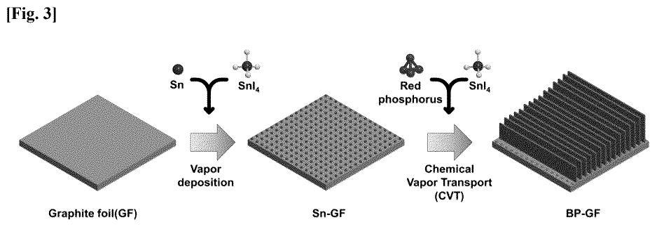

FIG. 3 is a schematic diagram of a method for directly synthesizing black phosphorus on a carbon substrate according to one example of the present disclosure.

Referring to FIG. 3, the Sn-graphite film (Sn-GF) was placed in a glass tube, and then red phosphorus, SnI₄, and Sn were added thereto. Thereafter, the glass tube was vacuum-sealed using a sealing apparatus. The thus-prepared glass tube was maintained at 550 °C for 24 hours and then slowly cooled to 450 °C over 12 hours. The temperature was maintained at 450 °C for 4 hours, and finally the sample was cooled to room temperature. Thereafter, the sample was obtained under an argon atmosphere, and impurities on the surface were removed by sonication with ethanol, acetone, and carbon disulfide.

### Example 2 Preparation of an Alkali Battery Using a Graphite Film on Which Black Phosphorus is Grown

The black phosphorus-graphite film prepared according to Example 1 was dried in a vacuum oven to remove internal moisture. The dried film was fabricated into an electrode having a diameter of 1 cm. Using the thus-prepared film, a sodium ion half-cell was prepared using 1 M NaPF6 in EC/DMC with 5 wt % FEC as an electrolyte, glass fiber as a separator, and 450 μm Na metal.

### Experimental Example 1 Confirmation of Structure and Crystallinity of a Graphite Film on Which Black Phosphorus is Grown

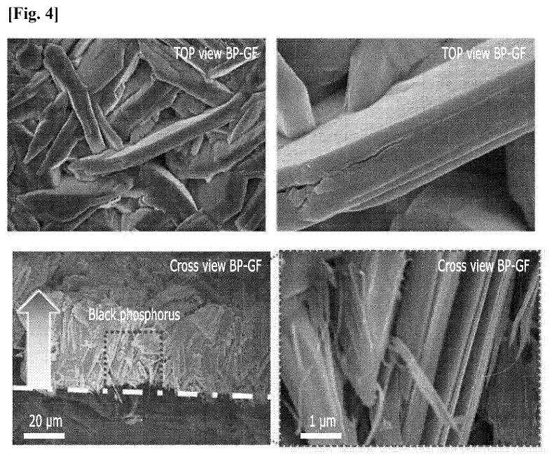

Referring to FIGS. 4 to 8, structural characteristics and crystallinity of the graphite film on which black phosphorus was grown, prepared according to Example 1, were confirmed.

FIG. 4 shows top-view and cross-sectional SEM images of a graphite film on which black phosphorus has been grown according to one example of the present disclosure.

Referring to FIG. 4, in the top-view SEM image, bulk particles may appear to have grown randomly, but referring to the cross-sectional SEM image, it was confirmed that innumerable films were bundled together. Through this, it was confirmed that the growth orientation of the black phosphorus was controlled.

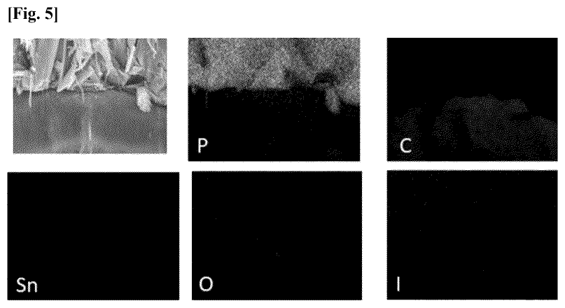

FIG. 5 is a cross-sectional EDS mapping image of a graphite film on which black phosphorus has been grown according to one example of the present disclosure.

Referring to FIG. 5, it was confirmed that a phosphorus layer was uniformly grown on a carbon layer.

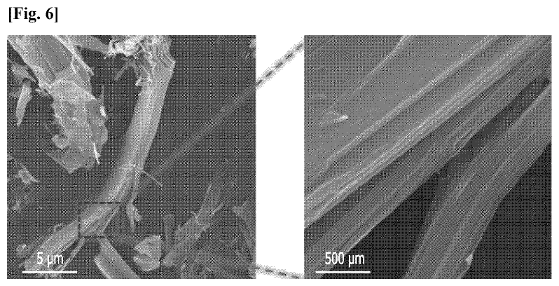

FIG. 6 is a particle image of grown black phosphorus according to one example of the present disclosure.

Referring to FIG. 6, it was confirmed that black phosphorus having a length of several μm to several tens of μm was grown, and a two-dimensional layered structure of the black phosphorus was confirmed.

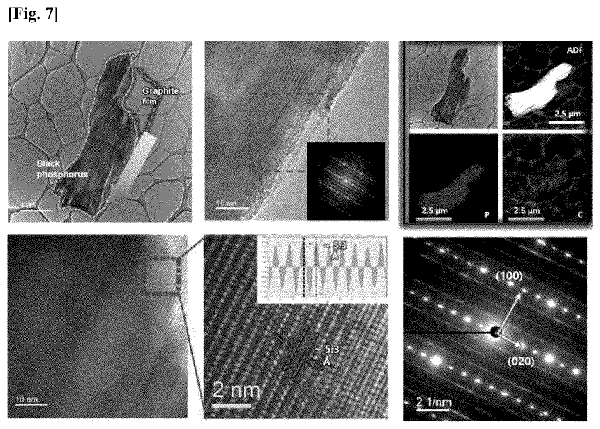

FIG. 7 is an HR-TEM image of black phosphorus according to one example of the present disclosure.

Referring to FIG. 7, it was confirmed that black phosphorus was grown on graphite, and it could be confirmed through the HR-TEM EDX image that pure black phosphorus was grown. In addition, it was confirmed through a high-magnification image and an SAED pattern that black phosphorus having excellent crystallinity was grown.

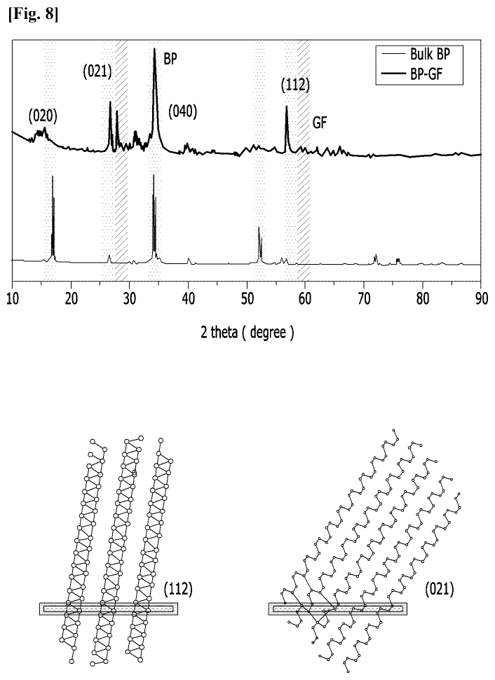

FIG. 8 is an XRD spectrum of a graphite film on which black phosphorus has been grown according to one example of the present disclosure.

Referring to FIG. 8, peaks overlapping with black phosphorus (BP) were confirmed, through which it was confirmed that black phosphorus having crystallinity was grown on the graphite film. In addition, it was confirmed that the (112) plane and the (021) plane appeared more dominantly than in conventional black phosphorus, indicating that the black phosphorus was grown in a nearly vertical orientation.

### Experimental Example 2 Evaluation of Sodium Ion Storage Capacity of the Black Phosphorus-Graphite Film Composite Anode Material

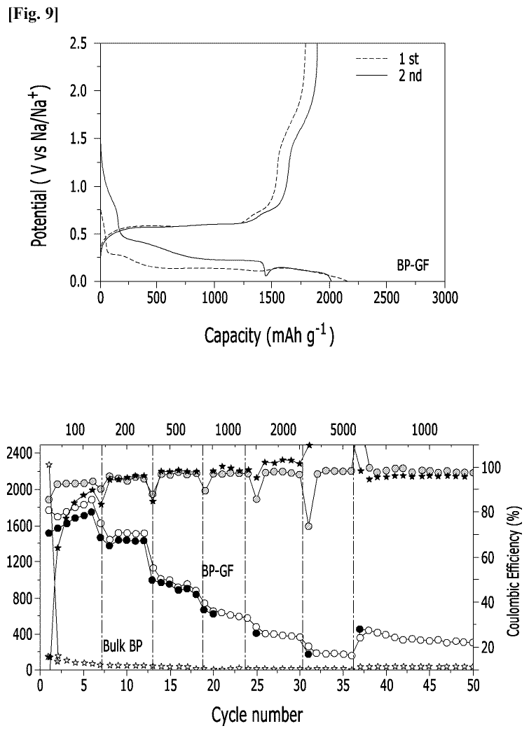

FIG. 9 shows results of measuring initial 2-cycle volumetric capacity and rate performance of an alkali battery using the graphite film on which black phosphorus has been grown according to Example 2 of the present disclosure.

Referring to FIG. 9, it was confirmed that the initial 2-cycle capacity had a value of 1,750 mAh/g, and that the initial Coulombic efficiency was also 84%. In addition, even in the rate-performance test, it was confirmed that the material exhibited a performance of 650 mAh/g at a rate of 1,000 mA/g. Through this, it was confirmed that the graphite film structure in which black phosphorus was uniformly grown improved sodium storage capability compared with bulk black phosphorus, provided stable cycle performance, and secured a high mass capacity even in initial cycles.

The aforementioned description of the present disclosure is to be exemplified, and it will be understood by those skilled in the art that the present disclosure may be easily modified in other detailed forms without changing the technical spirit or required features of the present disclosure. Therefore, it should be appreciated that the examples described above are illustrative in all aspects and are not restricted. For example, each component described as a singular form may be implemented in a distributed manner, and components described as being distributed may also be implemented in a combined form.

The scope of the present disclosure is represented by appended claims to be described below rather than the detailed description, and it is to be interpreted that the meaning and scope of the claims and all the changes or modified forms derived from the equivalents thereof come within the scope of the present disclosure.

What is claimed is:

1. A method for directly synthesizing black phosphorus on a carbon substrate, comprising:
coating a mineralizer on a surface of the carbon substrate; and
growing black phosphorus on the surface of the carbon substrate by placing the carbon substrate coated with the mineralizer and a black phosphorus precursor in a reactor and reacting them.

2. The method of claim 1, wherein the black phosphorus is grown on the surface of the carbon substrate with a controlled orientation.

3. The method of claim 1, wherein the mineralizer is selected from the group consisting of Sn, SnI₂, SnI₄, SnCl₂, SnCl₄, Pb, PbI₂, PbCl₂, Au, AuCl₃ and combinations thereof.

4. The method of claim 1, wherein the carbon substrate is selected from the group consisting of graphite film, carbon cloth, carbon nanotubes, graphene film, activated carbon, porous carbon, carbon fibers, buckypaper and combinations thereof.

5. The method of claim 1, wherein the black phosphorus precursor comprises red phosphorus, white phosphorus, and other phosphorus allotropes.

6. The method of claim 5, wherein the black phosphorus precursor further comprises a mineralizer of the same type as the mineralizer used for coating the carbon substrate.

7. The method of claim 1, wherein the coating and the growing are performed using a chemical vapor transport method.

8. The method of claim 7, wherein the coating of the mineralizer is performed at a temperature in a range of 550 °C to 900 °C.

9. The method of claim 1, wherein the growing black phosphorus is performed at a temperature in a range of 400 °C to 600 °C for 1 minute to 12 hours.

10. The method of claim 1, further comprising cooling to room temperature for stabilization of the black phosphorus, wherein the cooling to room temperature is performed for 4 hours to 24 hours.

11. A carbon substrate-black phosphorus composite, comprising:
a carbon substrate; and
black phosphorus grown on a surface of the carbon substrate with a controlled orientation.

12. The carbon substrate-black phosphorus composite of claim 11, wherein the black phosphorus has a form in which a plurality of films are stacked.

13. The carbon substrate-black phosphorus composite of claim 11, wherein the black phosphorus is bonded onto the carbon substrate by forming a chemical bond at an interface with the carbon substrate.

14. The carbon substrate-black phosphorus composite of claim 11, wherein the carbon substrate-black phosphorus composite is free of a conductive agent and a binder.

15. The carbon substrate-black phosphorus composite of claim 11, wherein the black phosphorus is crystalline.

16. An anode material for an alkali metal ion battery, comprising the carbon substrate-black phosphorus composite according to claim 11.

17. The anode material for an alkali metal ion battery of claim 16, wherein the alkali metal is lithium or sodium.

18. The anode material for an alkali metal ion battery of claim 16, wherein migration of the alkali metal ions is enhanced by the black phosphorus.
